(19) United States
(12) Patent Application Publication
(10) Pub. No.: US 2013/0122684 A1
(43) Pub. Date: May 16, 2013

(54) SEMICONDUCTOR PROCESS FOR REMOVING OXIDE LAYER

(71) Applicants: Teng-Chun Hsuan, Tainan City (TW); Ted Ming-Lang Guo, Tainan City (TW); Chin-Cheng Chien, Tainan City (TW)

(72) Inventors: Teng-Chun Hsuan, Tainan City (TW); Ted Ming-Lang Guo, Tainan City (TW); Chin-Cheng Chien, Tainan City (TW)

(21) Appl. No.: 13/293,144

(22) Filed: Nov. 10, 2011

(51) Int. Cl. H01L 21/265; H01L 21/76

(52) U.S. Cl. 438/400; 438/514; 438/530; 257/E21.334; 257/E21.54

(57) ABSTRACT

A semiconductor process for removing oxide layers comprises the steps of providing a substrate having an isolation structure and a pad oxide layer, performing a dry cleaning process and a wet cleaning process to remove said pad oxide layer, forming a sacrificial oxide layer on said substrate, and performing an ion implantation process to form doped well regions on both sides of the isolation structure.

### BACKGROUND OF THE INVENTION

1. Field of the Invention

The present invention relates generally to a semiconductor process, and more specifically, to a semiconductor process using a dry clean process and a wet clean process to etch oxide layers.

2. Description of the Prior Art

A conventional Local Oxidation of Silicon (LOCOS) isolation method is usually replaced by a method that forms a shallow trench isolation structure in circuit processes that are smaller than 250 nm, because of the bird's beak effect and the non-flatness of the surface. Although the shallow trench isolation structure can enhance component integration, it also gives rise to many problems that need to be solved in order to prevent the electrical properties and the isolation performance of the components from being degraded.

Take current common semiconductor process for example, multiple wet etching processes, for example wet cleaning by diluted hydrofluoric acid (HF), are necessary to remove oxides or clean the surface of substrate before the deposition of thin-film during the entire manufacturing process flow. In practice, the wet etching process may over-etch the STI structure, thereby forming a recessed region at the edges of the STI (referred generally as STI divot). The defect of the recessed region in STI structures more obvious with increased wet etching process.

FIG. 1 schematically depicts a cross-sectional view of a conventional shallow trench isolation structure. As shown in FIG. 1, a shallow trench isolation structure 120 is formed upon a substrate 110. The divots D1 and D2 are formed by over-etching at the edge of the top of the shallow trench isolation structure 120. As the gate structure crosses the edges of the shallow trench isolation structure 120, the conductive body of the gate structure located on the edge of the shallow trench isolation structure 120 collapses into the divots D1 and D2, increasing the local electrical fields and triggering too early the properties of transistors at the edge of the component area. This causes the hump phenomenon in the sub-threshold region of log Id-Vg. Furthermore, as the divots D1 and D2 extend and connect together so that they reduce the height of the shallow trench isolation structure 120, the gate structure that crosses the edges of the shallow trench isolation structure 120 will be short-circuited. This phenomenon becomes more obvious when the size of the semiconductor device shrinks and the channel width decreases, resulting in a diminution of the threshold voltage (Vₜₕ) of the device.

Therefore, it is still necessary for the industry to study and resolve the problem of recessed areas at both edges sides of the isolation structure resulting from the etching process of oxide layers.

### SUMMARY OF THE INVENTION

To resolve the issue of conventional STI divot defect prone to occur after repeated etching processes, the present invention provides an improved semiconductor process which replaces the conventional wet etching process with a dry cleaning process and a wet cleaning process to prevent the forming of recessed regions in the isolation structure and further improves the electrical performances of the semiconductor device to be made.

One purpose of the present invention is to provide a semiconductor process for removing an oxide layer, which comprises the steps of providing a substrate having an isolation structure and a pad oxide layer formed thereon, wherein the isolation structure divides the substrate into one first region and one second region, performing a dry cleaning process and a wet cleaning process to remove the pad oxide layer, forming a sacrificial oxide layer on the first region and the second region, and performing an ion implantation process to form doped well regions on the substrate.

Another purpose of the present invention is to provide a semiconductor process for removing an oxide layer, which comprises the steps of providing a substrate having an isolation structure to divide and a pad oxide layer formed thereon, wherein the isolation structure divides the substrate into one first region and one second region, performing a first removing process to remove said pad oxide layer, forming a sacrificial oxide layer on the first region and the second region, performing an ion implantation process to form doped well regions on the substrate, and then performing a second removing process to remove said sacrificial oxide layer, wherein at least one of the first removing process and the second removing process comprises a dry etching process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to ease the understanding of the embodiments, and are incorporated in and constitute a part of these specifications. The drawings illustrate some of the embodiments and, together with the description, serve to explain their principles. In the drawings:

FIG. 1 is a schematic cross-section view of a conventional shallow trench isolation (STI) in prior art.

FIGS. 2-11 illustrate the schematic cross-section views of a semiconductor process flow in accordance with the preferred embodiment of the present invention.

FIG. 2 is a schematic cross-section view illustrating the etching step of an isolation trench in the semiconductor process flow of present invention.

FIG. 3 is a schematic cross-section view of an isolation trench in accordance with the preferred embodiment of the present invention.

FIG. 4 is a schematic cross-section view illustrating the forming step of an isolation structure in the semiconductor process flow of the present invention.

FIG. 5 is a schematic cross-section view illustrating the removing step of a pad oxide layer by a dry cleaning process and a wet cleaning process in the semiconductor process flow of the present invention.

FIG. 6 is a schematic cross-section view of an isolation trench and a sacrificial oxide layer formed thereon in accordance with the preferred embodiment of the present invention.

FIG. 7 is a schematic cross-section view illustrating the ion implantation step for defining the doped well region in the semiconductor process flow of the present invention.

FIG. 8 is a schematic cross-section view of an isolation structure and the doped well region on both sides in accordance with the preferred embodiment of the present invention.

FIG. 9 is a schematic cross-section view illustrating the removing step of a sacrificial oxide layer by a dry cleaning process and a wet cleaning process in the semiconductor process flow of the present invention.

FIG. 10 is a schematic cross-section view illustrating the forming step of a gate dielectric layer in the semiconductor process flow of the present invention.

FIG. 11 is a schematic cross-section view of the isolation structure, the doped well region and the gate dielectric layer formed on both sides in accordance with the preferred embodiment of the present invention.

FIG. 12 is a TEM cross-sectional picture of the isolation structure made by the semiconductor process of the present invention.

FIG. 13 is a TEM cross-sectional picture of the isolation structure made by the semiconductor process of the prior art.

### DETAILED DESCRIPTION

FIGS. 2-11 schematically depict a cross-sectional view of a semiconductor process in accordance with one embodiment of the present invention. Please refer to FIGS. 2-11. First, as shown in FIG. 2, a substrate 210 is provided with a pad oxide layer 220 and a nitride layer 230 deposited thereon sequentially. Then, a lithography process is performed to form a patterned photoresist layer 240 and define an insulating area A. Pad oxide layer 220 is used as a stress buffering layer between substrate 210 and nitride layer 230 and has a thickness ranging from about tens of angstrom(A) to hundreds of angstrom, while the nitride layer 230 is used as the stop layer required in following CMP process and has a thickness ranging from about hundreds of angstrom to thousands of angstrom. The details of the pad oxide layer 220 and nitride layer 230 will be further described in the following embodiment. In the present invention, the substrate 210 may be a semiconductor substrate such as a silicon substrate, a silicon-containing substrate, epitaxial silicon substrate, a silicon germanium substrate, silicon carbide substrate, or a silicon-on-insulator (SOI) substrate. In this embodiment, the substrate 210 is a silicon substrate, the pad oxide layer 220 is a silicon dioxide layer, and the nitride layer 230 is a silicon nitride layer. In other embodiment of present invention, an anti-reflective layer (not shown) may be provided under the photoresist layer 240. The pad oxide layer 220 and nitride layer 230 may be replaced by layer structures formed by other materials, such as carbon-containing or silicon-containing material suitable for hard mask.

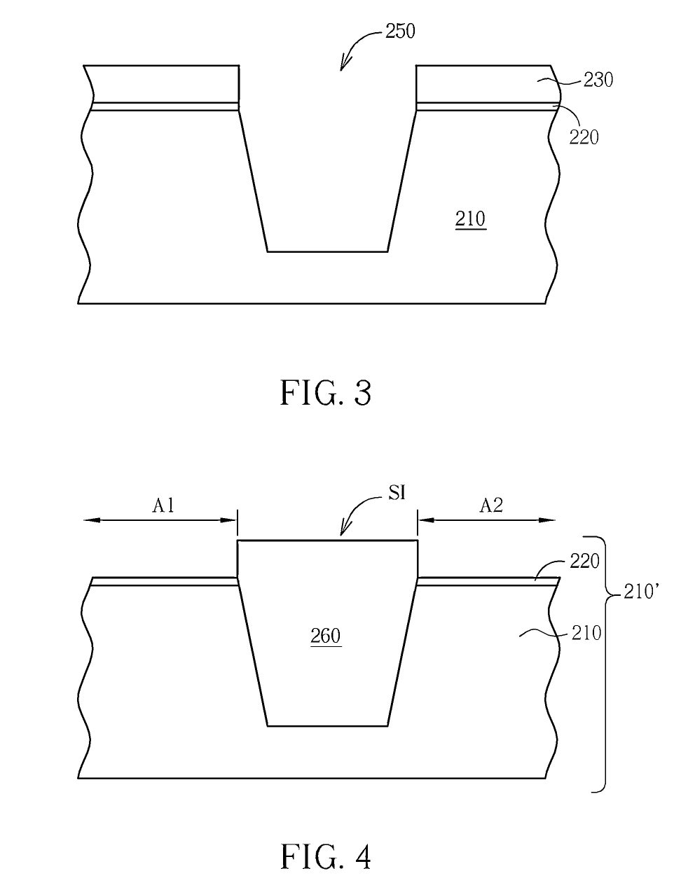

Subsequently, a single etching process or successive etching processes are performed. As shown in FIG. 2, the nitride layer 230 and the pad oxide layer 220 are first patterned by using the photoresist layer 240 as an etching mask. The substrate 210 is then etched by using the patterned nitride layer 230 as an etching mask to form a trench 250 (as shown in FIG. 3) by using photoresist layer 240 as a mask for etching. The depth of the trench 250 is between 300 nm and 700 nm. A liner (not shown) may be optionally formed on the inner sides of the trench 250 to eliminate damages caused during the etching process, wherein the liner may be an oxide layer, and it may be formed by methods such as a thermal oxidation method, etc., but not limited thereto.

As shown in FIG. 4, an isolation structure 260 is filled in the trench 250 by methods such as chemical vapor deposition (CVD) or high aspect ratio process (HARP), high density plasma chemical vapor deposition (HDPCVD), and atmosphere pressure chemical vapor deposition (APCVD), etc. Then, the protruding portion of the isolation structure 260 from the substrate 210 is removed by applying a CMP process and using the nitride layer 230 as a polish stop layer, thereby forming a flat surface S1 of the isolation structure 260 flushed with the top surface of the nitride layer 230. The nitride layer 230 is then removed by using etchant such as hot phosphoric acid. This way, an isolation structure 260 protruding from the substrate 210 and the pad oxide layer 220 is, therefore, formed. In other embodiments, the isolation structure 260 may be, but not limited to, a field oxide layer (FOX).

As shown in FIG. 4, a substrate 210′ of the present invention is formed including an isolation structure 260 and a pad oxide layer 220. The isolation structure 260 divides the substrate 210′ into a plurality of active regions, such as a first region A1 and a second region A2. The pad oxide layer 220 is located on the surface of the first region A1 and the second region A2.

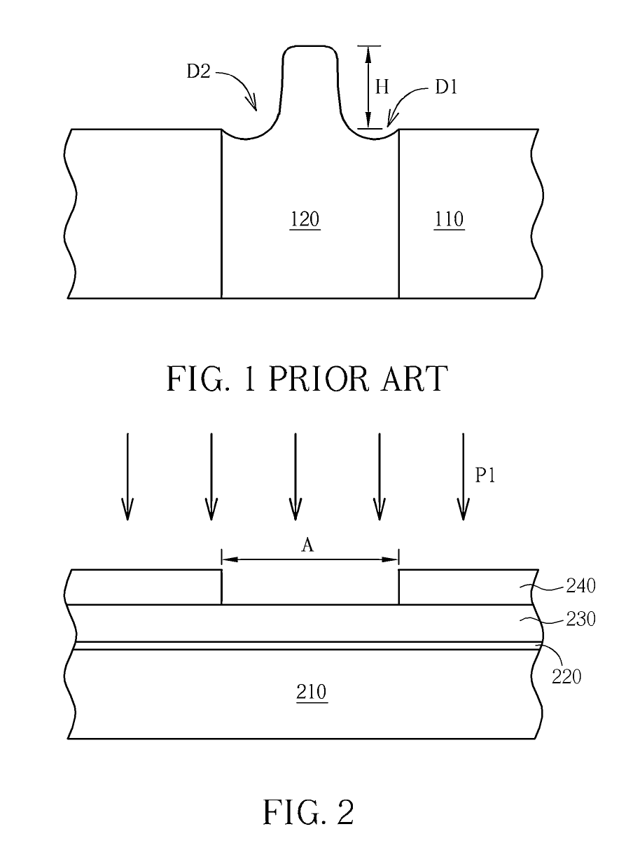

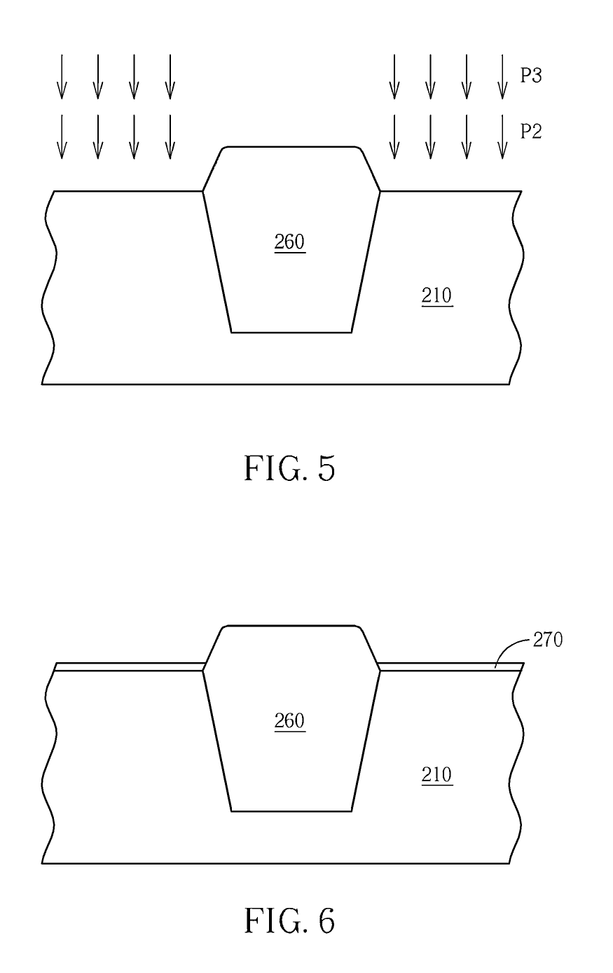

As shown in FIG. 5, a first removing process is performed to remove the pad oxide layer 220, wherein said first removing process at least includes a first dry cleaning process P2. As far as this step is concerned, the pad oxide layer 220 is usually treated by a wet etching process in conventional semiconductor process flow. The material of the pad oxide layer 220 is similar to that of the isolation structure 260; both of them may be composed of oxides, for example. The wet etching process is an isotropic etching process, such that the etch selectivity of the wet etching process for the pad oxide layer 220 and the isolation structure 260 is bad, causing a portion of the isolation structure 260 to be undesirably etched during the etching process of the pad oxide layer 220. This may lead to the so-called STI divot being formed on the isolation structure 260 (shown as D1 and D2 in FIG. 1) and further result in the abovementioned problems of the prior art. In comparison with the means of prior art, the present invention applies an anisotropic dry cleaning process instead, so that the dry cleaning process P2 has an etch selectivity for the pad oxide layer 220 and the isolation structure 260 better than the one of the prior art, thereby preventing the issue of over-etching on the isolation structure. Furthermore, the modulation of parameters in the dry cleaning process P2 are more flexible than in the wet etching process, therefore the desired shape of the isolation structure 260 can be obtained precisely. In this embodiment, the dry cleaning process P2 may be, but not limited to, a SiCoNi dry cleaning process or a Certas dry cleaning process. The dry cleaning process P2 may also include a nitrogen trifluoride and ammonia containing dry cleaning process.

For example, in one preferred embodiment of present invention, a SiCoNi remote plasma dry cleaning process is utilized with a possible change in the chemical compositions is shown as follows:
etchant generated: NF₃+NH₃→NH₄F+NH₄F.HF
etching: NH₄F+NH₄F.HF+SiO₂→(NH₄)₂SiF₆₍ₛ₎+H₂O (with the wafer temperature during etching>35° C.)
annealing: (NH₄)₂SiF₆₍ₛ₎→SiF_{4(g)}+NH_{3(g)}+HF_{(g)} (with the wafer temperature during annealing>100° C.)

And in another embodiment of present invention, for example, a Certas dry cleaning process is utilized with a possible change in the chemical compositions is shown as follows:
etchant generated: SiO₂+4HF→SiF₄+2H₂O SiF₄+2HF+2NH₃→(NH₄)₂SiF₆
Post heating treatment: (NH₄)₂SiF₆→SiF₄)+NH₃+HF (the byproduct is sublimated from the wafer surface by heating from room temperature to 250° C.)

Furthermore, in some embodiments of present invention, the first removing process may optionally include an additional first wet cleaning process P3 after the first dry cleaning process P2 for further cleaning the surface of substrate 210. To be more specifically, since some fluoride ions and metal contaminants may remain after the SiCoNi dry cleaning process, the wet cleaning process P3 is further performed to remove the remaining fluoride ions and impurities, such as native oxide on the substrate 210. And since most of the pad oxide layer 220 has been removed by previous first dry cleaning process P2, the thickness of remained pad oxide layer 220 is less than 10 Å. The process time of isotropic first wet cleaning process P3 may be significantly shorten. In this embodiment, the wet cleaning process P3 is a hydrofluoric acid-containing cleaning process. The processing time of the wet cleaning process P3 is preferably ranging from several seconds to tens of seconds. Moreover, after the wet cleaning process P2 is performed, a standard clean 1 (SC1) and a standard clean 2 (SC2) may be optionally performed to further remove the fluoride ions and impurities, without degrading the shape of the isolation structure 260. At this stage, an isolation structure 260 having no defect feature (i.e. divots) is, therefore, formed.

Please refer to FIG. 6, a sacrificial oxide layer 270 is formed on the surface of substrate 210 and isolation structure 260 after removing the pad oxide layer 220 by first dry cleaning process P2 and first wet cleaning process P3. The function of sacrificial oxide layer 270 is to enhance the scattering degree of implantation in a following ion implantation process, thereby better controlling the formed profile of doped well region, as well as preventing the contamination of substrate 210 resulting from a direct contact with the photoresist. In the embodiment of the present invention, the sacrificial oxide layer 270 may be formed by a thermal oxidation process, such as a rapid thermal oxidation process (RTO), and has a thickness ranging from tens of angstrom to 110 Å.

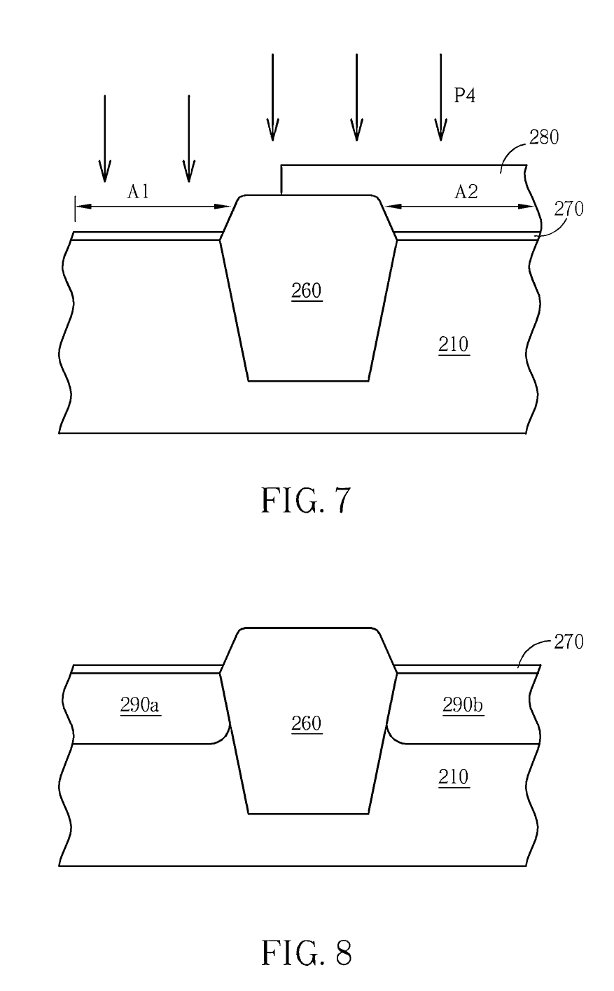

Please refer subsequently to FIG. 7, an ion implantation process is performed to define the doped well region on the predetermined portion of substrate 210 after forming the sacrificial oxide layer 270. Take the defining of a P-well region for example, as shown in the figure, the isolation structure 260 and the second region A2 on the substrate 210 are coated with a photoresist layer 280, used as the mask for ion implantation, so that only the first region Al of the substrate exposed by the photoresist layer 280, may be implanted by the dopants (ex. boron) and thereby form a P-well region. The same process may be applied on the second region A2 in another side of the isolation structure 260. The implantation of dopants, such as phosphorus and arsenic, on the second region A2 may form a relative N-well region.

FIG. 8 illustrates schematically the cross-sectional view of the substrate after defining the doped well regions by the ion implantation process and stripping off the photoresist layer 280. As shown in the figure, the doped well regions 290a and 290b, for example, a N-well and a P-well, are formed respectively on both sides of the isolation structure 260 to construct a substrate suitable for CMOS devices. Please note that the doped well regions 290a and 290b can be doped regions of the same type, depending on the desired semiconductor device to be made.

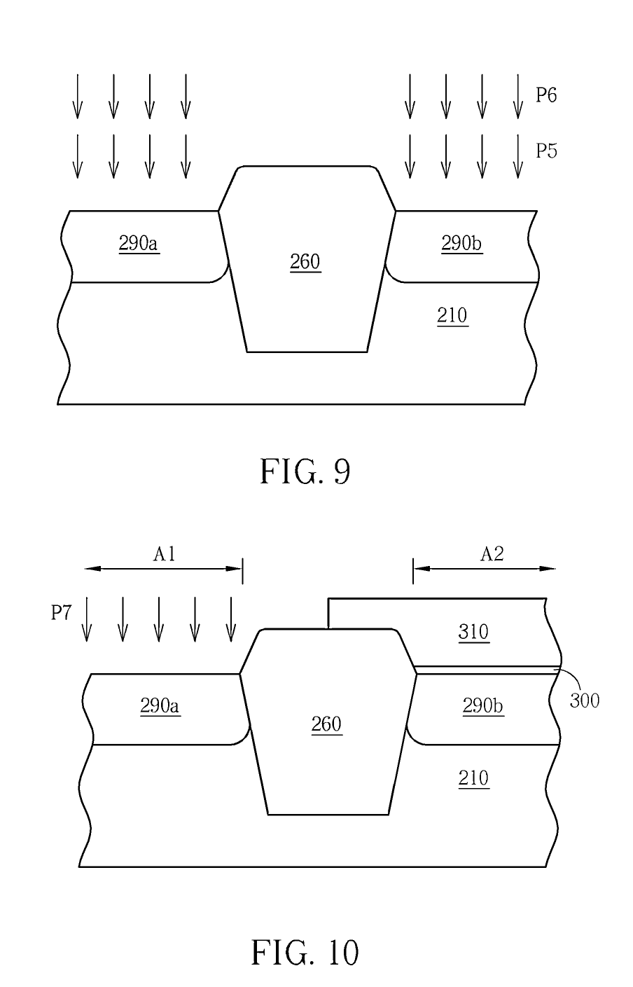

After defining the doped well regions 290a and 290b, as shown in FIG. 9, performing a second removing process similar to the ones shown in the step of removing pad oxide layer 220 (P2 and P3 shown in FIG. 5) to remove the sacrificial oxide layer 270. In one embodiment of present invention, the second removing process may include a second dry cleaning process P5 and a second wet cleaning process P6. Similarly, in present embodiment, the modulation of the parameters in the second dry cleaning process P5 is more flexible than during a conventional wet etching process, therefore the desired shape of the isolation structure 260 can be obtained precisely. Also, the second wet cleaning process P6 may further remove the remaining fluoride ions and impurities, such as native oxides on the substrate 210. The combination of the dry cleaning and wet cleaning processes may achieve an isolation structure 260 with better shape and electrical performances.

In this embodiment, the dry cleaning process P5 may be, but not limited to, a SiCoNi dry cleaning process or a Certas dry cleaning process, wherein the SiCoNi remote plasma dry cleaning process is preferred. The dry cleaning process P5 may also include a nitrogen trifluoride and ammonia containing dry cleaning process. The wet cleaning process P6 may be a hydrofluoric acid-containing cleaning process, and the processing time of the wet cleaning process P6 is preferably 15 seconds. Moreover, after the wet cleaning process P6 is performed, a standard clean 1 (SC1) and a standard clean 2 (SC2) may be optionally performed to further remove the fluoride ions and impurities, without degrading the shape of the isolation structure 260. At this stage, a perfect isolation structure 260 with doped well region defined on both sides and without divot defects is, therefore, formed.

For later steps of the process flow, as shown in FIG. 10, general semiconductor processes may be performed on the substrate after the defining of doped well regions, such as forming a dielectric layer 300 on the first region A1 and the second region A2. In this embodiment, the thickness of the dielectric layer to be formed on the first region A1 is thinner than the thickness of the dielectric layer to be formed on the second region A2, which is meant for applying the dielectric layer on the first region A1 to high voltage components and applying the dielectric layer on the second region A2 to low voltage components. This means that the dielectric layer 300 on the first region A1 may be removed first and a thinner dielectric layer is then formed. A patterned photoresist 310 is first formed to protect the dielectric layer 300 thereunder, and an etching process is then performed to remove the dielectric layer 300 on the first region A1. The forming process of the dielectric layer 300 may be a thermal oxidation process. In this embodiment, the forming process of the dielectric layer 300 is a rapid thermal oxidation process, but it is not limited to. CVD process is also practicable in this case. The method of etching the dielectric layer 300 on the first region A1 may be a wet etching process P7. In this embodiment, the wet etching process P7 is a buffered oxide etching (BOE) process, but it is not limited thereto. The dielectric layer 300 on the first region A1 is removed in this embodiment, but in another embodiment, it maybe the dielectric layer 300 on the second region A2 to be removed instead.

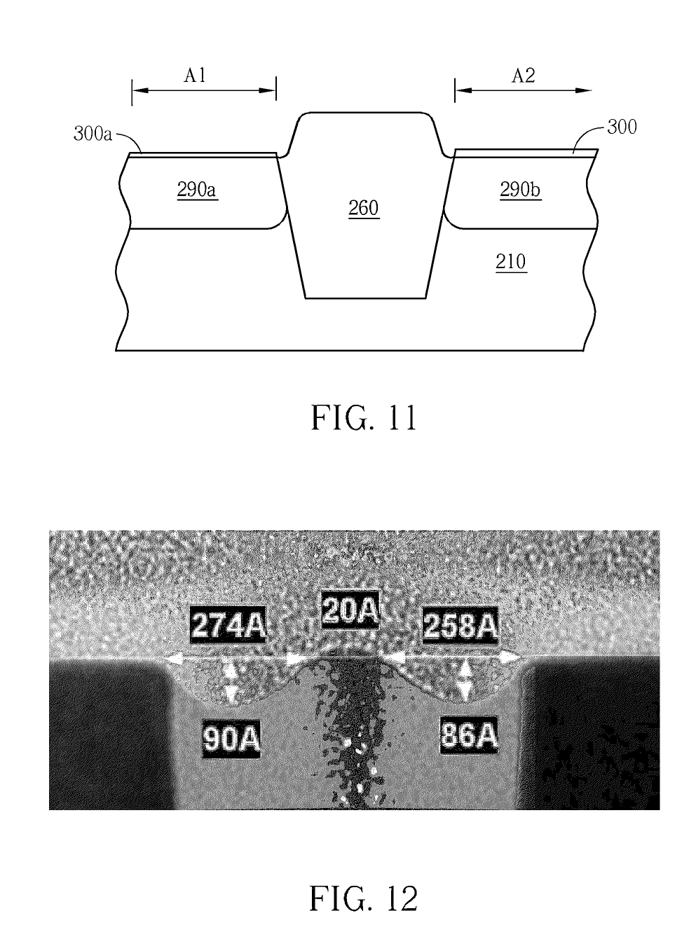

As shown in FIG. 11, a dielectric layer 300a thinner than the dielectric layer 300 is deposited so that the manufacturing of different thicknesses of the dielectric layer 300 and 300a is completed. The dielectric layer 300 of the present invention may be a gate dielectric layer, and a gate structure may be further formed thereon. For example, a gate electrode layer (not shown) maybe formed after the wet etching process P7. Thereafter, a gate electrode layer and a gate dielectric layer are patterned, and a spacer and a source/drain region etc. may be sequentially formed. The numbers of the removed dielectric layer and the isolation structure 260 in this embodiment are just examples applied in the present invention, wherein the numbers of the removed dielectric layer and the isolation structure 260 depend upon practical circumstances. Those equivalents and alternatives applying the spirit of present invention should be considered as been falling within the scope of the present invention as defined by the present disclosure.

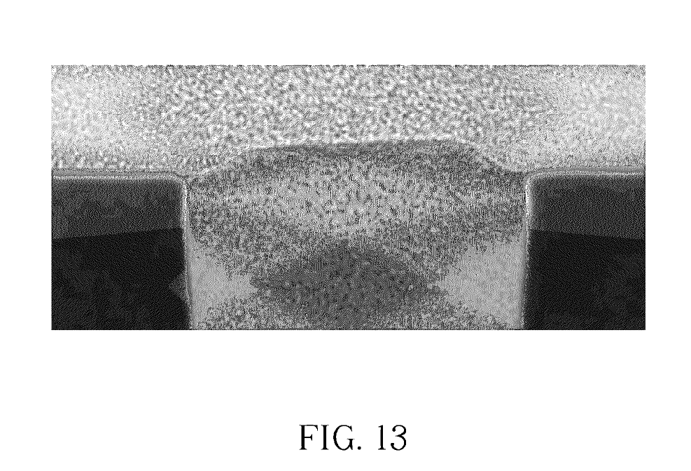

Please refer now to FIG. 12 and FIG. 13 which show the cross-sectional Transmission Electron Microscopy (TEM) pictures of the isolation structure made respectively by the semiconductor process flow of the prior art and of the present invention. In conventional process, as shown in FIG. 12, the oxide layer (ex. abovementioned pad oxide layer and SAC layer) formed on the substrate is removed by wet etching process using diluted hydrofluoric acid in a cleaning solution, with time duration about 260 sec or 300 sec. It is observed that obvious recess regions are formed on both sides of the isolation structure, due to the over-etching of repeated wet etching processes with long duration. In the exemplary aspect of prior art, the depth of recessed region may reach about 20 Å, while the width of the recessed region may reach about 270 Å. The recessed regions on both sides are nearly merged. In this aspect, the gate structure on both sides of the isolation structure will be bridged and short-circuited

In contrast, as shown in FIG. 13, the original shape of the isolation structure made by the process flow of present invention is maintained after the defining of the doped well regions on both sides. No recessed areas or surface are observed. In comparison to the prior art using conventional wet etching processes having long time durations, the present invention is mainly based on a dry cleaning process combined with a quick wet cleaning process to efficiently prevent the isolation structure from being over-etched and maintain an ideal shape.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor process for removing oxide layers, comprising:
providing a substrate, comprising an isolation structure and a pad oxide layer, wherein the isolation structure divides the substrate into at least one first region and one second region, and the pad oxide layer is located on the surfaces of the first region and the second region;
performing a dry cleaning process and a wet cleaning process to remove the pad oxide layer;
forming a sacrificial oxide layer on the first region and the second region; and
performing an ion implantation process to form doped well regions in the first region and the second region.

2. The semiconductor process according to claim 1, wherein the dry cleaning process comprises a nitrogen trifluoride and ammonia containing dry cleaning process.

3. The semiconductor process according to claim 1, wherein the dry cleaning process comprises a SiCoNi remote plasma dry cleaning process.

4. The semiconductor process according to claim 1, wherein the wet cleaning process comprises a hydrofluoric acid-containing wet cleaning process.

5. The semiconductor process according to claim 4, wherein the processing time of the hydrofluoric acid-containing cleaning process is ranging from several seconds to tens of seconds.

6. The semiconductor process according to claim 1, wherein the sacrificial oxide layer is formed by a thermal oxidation process.

7. The semiconductor process according to claim 6, wherein the sacrificial oxide layer is formed by a rapid thermal oxidation process.

8. The semiconductor process according to claim 1, wherein the isolation structure comprises a shallow trench isolation structure or a field oxide layer.

9. The semiconductor process according to claim 8, wherein the shallow trench isolation structure is formed by a high aspect ratio process (HARP), high density plasma chemical vapor deposition (HDPCVD), or atmospheric pressure chemical vapor deposition (APCVD).

10. The semiconductor process according to claim 1, wherein the thickness of the pad oxide layer is ranging from tens of angstrom to hundreds of angstrom.

11. The semiconductor process according to claim 1, wherein the thickness of the sacrificial oxide layer is ranging from tens of angstrom to 110 Å.

12. The semiconductor process according to claim 1, further comprising forming a gate dielectric layer after removing the sacrificial oxide layer.

13. The semiconductor process according to claim 12, further comprising performing a buffered oxide etching (BOE) process after forming the gate dielectric layer.

14. The semiconductor process according to claim 1, further comprising performing a standard clean 1 (SC1) process after the wet cleaning process.

15. The semiconductor process according to claim 1, further comprising performing a standard clean 2 (SC2) process after the wet cleaning process.

16. A semiconductor process for removing oxide layers, comprising:
providing a substrate comprising an isolation structure and a pad oxide layer, wherein the isolation structure divides the substrate into at least one first region and one second region, and the pad oxide layer is located on the surfaces of the first region and the second region;
performing a first removing process to remove the pad oxide layer;
forming a sacrificial oxide layer on the first region and the second region;
performing an ion implantation process to form doped well regions in the first region and the second region; and
performing a second removing process to remove the sacrificial oxide layer, wherein at least one of the first removing process and the second removing process comprises a dry etching process.

17. The semiconductor process according to claim 16, wherein said dry etching process comprises a nitrogen trifluoride and ammonia containing dry cleaning process.

18. The semiconductor process according to claim 16, wherein the dry etching process comprises a SiCoNi remote plasma dry cleaning process.

19. The semiconductor process according to claim 16, wherein the first removing process further comprises a wet etching process.

20. The semiconductor process according to claim 16, wherein the second removing process further comprises a wet etching process.

21. The semiconductor process according to claim 19, wherein the wet etching process comprises a hydrofluoric acid-containing wet cleaning process.

22. The semiconductor process according to claim 20, wherein the wet etching process comprises a hydrofluoric acid-containing wet cleaning process.

23. The semiconductor process according to claim 21, wherein the processing time of the hydrofluoric acid-containing wet cleaning process ranging from several seconds to tens of seconds.

24. The semiconductor process according to claim 16, wherein the sacrificial oxide layer is formed by a thermal oxidation process.

25. The semiconductor process according to claim 24, wherein the sacrificial oxide layer is formed by a rapid thermal oxidation process.

26. The semiconductor process according to claim 16, wherein the isolation structure comprises a shallow trench isolation structure or a field oxide layer.

27. The semiconductor process according to claim 26, wherein the shallow trench isolation structure is formed by a high aspect ratio process (HARP), high density plasma chemical vapor deposition (HDPCVD) or atmospheric pressure chemical vapor deposition (APCVD).

28. The semiconductor process according to claim 16, wherein the thickness of the pad oxide layer is ranging from tens of angstrom to hundreds of angstrom.

29. The semiconductor process according to claim 16, wherein the thickness of the sacrificial oxide layer is ranging from tens of angstrom to 110 Å.

30. The semiconductor process according to claim 16, further comprising forming a gate dielectric layer after removing the sacrificial oxide layer.

31. The semiconductor process according to claim 30, further comprising performing a buffered oxide etching (BOE) process after forming the gate dielectric layer.

32. The semiconductor process according to claim 19, further comprising performing a standard clean 1 (SC1) process after the wet etching process.

33. The semiconductor process according to claim 20, further comprising performing a standard clean 1 (SC1) process after the wet etching process.

34. The semiconductor process according to claim 19, further comprising performing a standard clean 2 (SC2) process after the wet etching process.

35. The semiconductor process according to claim 20, further comprising performing a standard clean 2 (SC2) process after the wet etching process.
